(19) United States
(12) Patent Application Publication
(10) Pub. No.: US 2026/0023125 A1
(43) Pub. Date: Jan. 22, 2026

(54) BATTERY SELF-DISCHARGE DETECTION

(71) Applicant: FORD GLOBAL TECHNOLOGIES, LLC, Dearborn, MI (US)

(72) Inventors: Gunho KWAK, Novi, MI (US); Keonseok OH, Novi, MI (US); Yooseong LEE, Novi, MI (US); Chi PAIK, Grosse Ile, MI (US); Boualem MEKHALDI, Wolverine Lake, MI (US); Hussein OTHMAN, Plymouth, MI (US); Rakesh NAHTA, Bloomfield Hills, MI (US)

(21) Appl. No.: 18/778,198

(22) Filed: Jul. 19, 2024

(51) Int. Cl. G01R 31/385; H01M 10/0525; H01M 10/42; H01M 10/44

(52) U.S. Cl. CPC G01R 31/3865; H01M 10/0525; H01M 10/4285; H01M 10/446

(57) ABSTRACT

A power source has an output voltage matched to a voltage of, and connected with, a battery cell. A current meter measures a magnitude of current flow from the power source to the battery cell. A controller flags the battery cell as operable responsive to the magnitude being less than a predefined threshold after a predefined period of time that begins with the power source being connected with the battery cell.

### TECHNICAL FIELD

The present disclosure generally relates to a method and system for detecting a battery self-discharge. More specifically, the present disclosure relates to a method and system for detecting an internal self-discharge of a battery during manufacture.

### BACKGROUND

Electric vehicles and hybrid electric vehicles may rely on one or more rechargeable batteries for providing electric energy to a motor for propulsion.

### SUMMARY

A method includes adjusting an output voltage of a power source to match a voltage of a battery cell, connecting the power source to the battery cell, and removing the battery cell from a manufacturing line responsive to a magnitude of current flow from the power source to the battery cell being greater than a predefined threshold after a predefined period of time that begins with the connecting.

A test apparatus includes a power source having an output voltage matched to a voltage of, and connected with, a battery cell, a current meter that measures a magnitude of current flow from the power source to the battery cell, and a controller that flags the battery cell as operable responsive to the magnitude being less than a predefined threshold after a predefined period of time that begins with the power source being connected with the battery cell.

A method includes adjusting an output voltage of a power source to a voltage of a battery cell such that the output voltage is at least equal to and no more than a predefined value greater than the voltage, connecting the power source to the battery cell, and grading the battery cell according to a magnitude of current flow from the power source to the battery cell.

### BRIEF DESCRIPTION OF THE DRAWINGS

FIG. 1 is an example block topology of an electrified vehicle illustrating energy storage components.

FIG. 2 is a schematic diagram of a battery self-discharge detecting system.

FIG. 3 is a waveform diagram illustrating an external self-discharge current.

FIG. 4 is a flow diagram of a process for detecting defective battery cells based on self-discharging.

FIG. 5 is a waveform diagram illustrating the current characteristics of different grades of battery cells.

### DETAILED DESCRIPTION

Embodiments of the invention are described in this document. These embodiments are provided as examples, and other embodiments may take different forms. The figures included are not necessarily drawn to scale; some features may be exaggerated or minimized to highlight specific components. Consequently, the specific structural and functional details disclosed should not be viewed as restrictive but as a basis for educating those skilled in the art.

Features shown and described in connection with any one figure may be combined with features from one or more other figures to create embodiments not explicitly illustrated or described. The illustrated combinations represent typical applications. However, various combinations and modifications of these features, consistent with the teachings of this disclosure, may be desirable for specific applications or implementations.

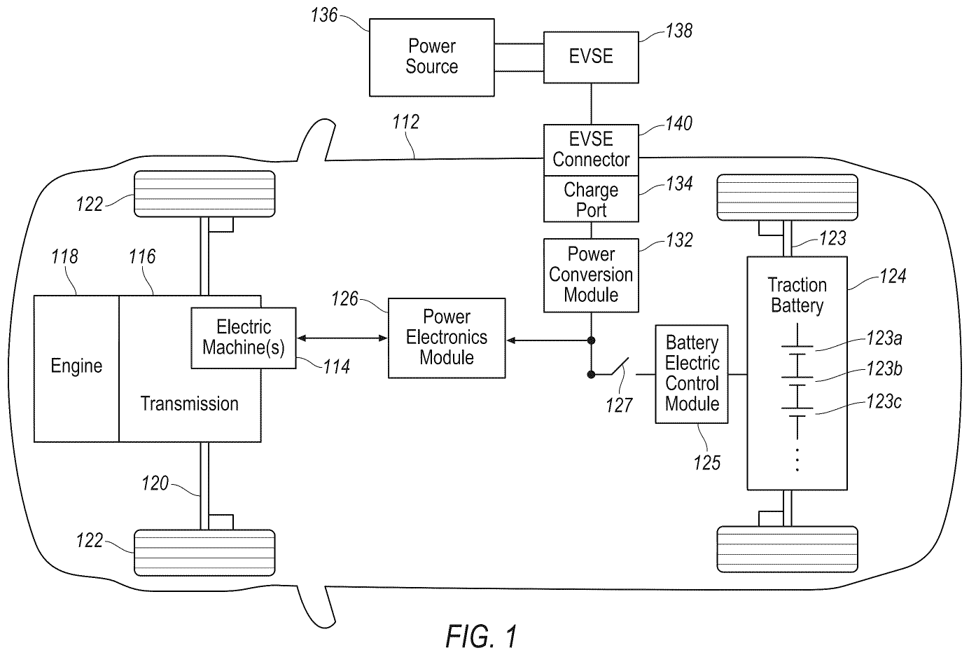

FIG. 1 illustrates the powertrain and power storage components of a plug-in hybrid-electric vehicle (PHEV) 112. The PHEV 112 includes one or more electric machines (electric motors) 114 mechanically coupled to a hybrid transmission 116. These electric machines 114 can operate as both motors and generators. The hybrid transmission 116 is also mechanically linked to an internal combustion engine 118 and a drive shaft 120, which is connected to wheels 122. The electric machines 114 provide propulsion and slowing capabilities whether the engine 118 is running or not. Additionally, these electric machines 114 can function as generators, recovering energy that would otherwise be lost as heat in the friction braking system, thereby enhancing fuel economy. They also help reduce vehicle emissions by allowing the engine 118 to operate at more efficient speeds and enabling the vehicle 112 to run in electric mode with the engine 118 off under certain conditions.

A traction battery or battery pack 124 stores energy used by the electric machines 114. The battery pack 124 includes multiple battery cells 123 connected in series to deliver a high-voltage DC output. These cells 123 can be of various types, such as rechargeable lithium-ion cells, and can be arranged in pouch or prismatic forms. As depicted in FIG. 1, the first battery cell 123a has a positive and a negative terminal. The second cell 123b connects its positive terminal to the negative terminal of the first cell 123a, and the third cell 123c connects similarly to the second cell 123b. Although the current example shows the battery cells 123 connected in series, other configurations may be used depending on the specific design requirements. The term “battery cell” in this context can refer to a single cell, an array of cells connected in series, or similar configurations.

The traction battery 124 is electrically connected to one or more battery electric control modules (BECM) 125, equipped with processors and software to monitor and control the battery's operations. Additionally, the traction battery 124 is connected to power electronics modules 126, also known as power inverters. Contactors 127 can isolate or connect the traction battery 124 and BECM 125 to other components. The power electronics module 126 facilitates bi-directional energy transfer between the traction battery 124 and electric machines 114. It converts DC voltage from the traction battery 124 to three-phase AC current required by the electric machines 114, and during regenerative braking, it converts AC current from the electric machines 114 back to DC voltage for storage in the traction battery 124. This description is also applicable to pure electric vehicles (BEVs), where the hybrid transmission 116 might be a gearbox connected to the electric machine 114, and the engine 118 is absent.

The vehicle 112 can be either a battery electric vehicle (BEV) or a plug-in hybrid electric vehicle (PHEV) with the traction battery 124 rechargeable via an external power source 136. This external power source 136, which could be an electrical outlet or a power grid provided by an electric utility company, connects to electric vehicle supply equipment (EVSE) 138. The EVSE 138 manages the energy transfer from the power source 136 to the vehicle 112 and can manage both DC and AC power. It connects to the vehicle's charge port 134 through a charge connector 140. The charge port 134, which transfers power from the EVSE 138 to the vehicle 112, is electrically connected to an onboard power conversion module 132. This module conditions the incoming power to the appropriate voltage and current levels for the traction battery 124 and coordinates power delivery from the EVSE 138. The EVSE connector 140 mates with the charge port 134, and power transfer can also occur wirelessly through inductive coupling.

As previously mentioned, the traction battery 124 comprises multiple individual battery cells 123 that provide energy storage. The performance and longevity of the traction battery 124 depend significantly on the quality of these cells 123, which can be affected by various factors during manufacturing. For instance, foreign object contamination can occur during production, leading to internal current circulations and self-discharge within the cells 123, even when they are not connected to any external load. The severity of contamination can result in varying self-discharge currents, from microamps to milliamps. Although larger contaminations are less common, even small-scale contaminations can cause significant self-discharge over time, reducing the state of charge (SOC) when the vehicle is parked for extended periods. Therefore, identifying and removing defective cells during the manufacturing process may be helpful before their installation in the traction battery 124.

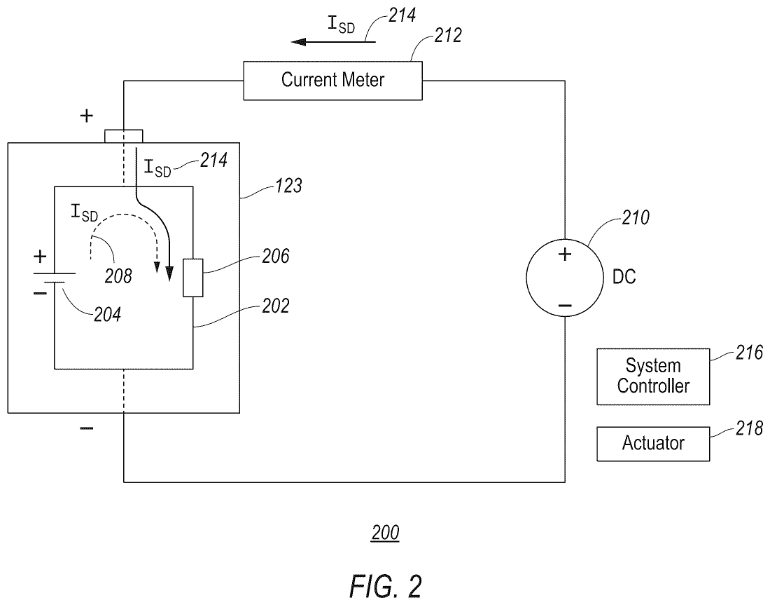

Referring to FIG. 2, a schematic diagram of a battery self-discharge detecting system 200 (the system 200) is shown. In this example, the system 200 may be utilized at the formation stage of the cell manufacturing process. At the formation stage, a newly assembled one of the battery cells 123 may be charged (and/or discharged) to activate the battery material. Once the battery is charged, the self-discharge (possibly caused by foreign object contamination) may be detectable by the system 200.

To better describe the system 200, FIG. 2 illustrates an equivalent circuit model (ECM) 202 of a newly manufactured one of the battery cells 123. More specifically, the ECM 202 may resemble a closed-circuit loop including a battery power source 204 providing an open circuit voltage (OCV) and an internal resistor 206 which resembles the internal resistance of the battery cell (possibly caused by the foreign object contaminations). In an ideal situation in which no defect exists, the internal resistor 206 should approach infinity such that the ECM loop is open and no internal circulation current is able to pass through the internal resistor 206. Thus, no (or very little) self-discharge current exists in ideal situations. In reality, however, various defects or imperfections exist. Thus, even if the battery cell 123 is disconnected from other external loads, it may be common for a self-discharge current I_{SD} 208 generated from the battery power source 204 flowing through the internal resistor 206 of the ECM loop to exist.

Due to the small magnitude of the self-discharge current I_{SD} 208 (e.g., usually in the range of microamps), it may be difficult to detect the self-discharge current I_{SD} ) 208 in a timely manner. Conventional self-charge current detecting methods involve battery manufacturers charging the newly formed battery cells 123 to reach a specific state of charge (SOC) and waiting for days (even weeks) for the SOC to drop. For instance, the battery cell 123 may be charged to 50% SOC which in this example is equivalent to 3.65V OCV across the positive and negative terminals. Assuming the battery cell 123 at issue experiences a 10 μA self-discharge current, this self-discharge current may result in a reduced terminal voltage of 3.63V after sitting for seven days. The reduced voltage of 0.02V over the seven-day waiting period may help the manufacturer identify the battery cell 123 as being defective. However, this conventional self-discharge current detecting method takes a long time.

The present disclosure proposes a battery self-discharge detecting system 200 to detect and identify one or more battery cells 123 experiencing self-discharge in a shorter period of time (e.g., in seconds or minutes). Referring to FIG. 2, the system 200 may include an external power source 210 configured to provide a DC voltage to the newly formed and charged battery cell 123. The external power source 210 may be configured to provide a DC voltage precisely matching the OCV of the battery cell 123 (e.g., with approximately 3 μV precision). The system 200 may further include a current meter 212 connected between the battery cell 123 and external power source 210 and configured to measure a current between the two. In this example, the current meter 212 is connected between the positive terminals of the battery cell 123 and the external power source 210. In an alternative example, the current meter 212 may be connected between the negative terminals of the battery cell 123 and the external power source 210 under essentially the similar principle. The current meter 212 may be configured to measure a precise amperage (e.g., in the range of microamps) flowing between the battery cell 123 and external power source 210. As discussed above, since the voltage of the external power source closely matches the voltage of the OCV of the battery cell 123, the current flowing through the current meter 212 should be very small. In an ideal situation, when equivalent internal resistor 206 is infinitely high (e.g., no internal current I_{SD} ), the current meter 212 should measure little to zero current. However, if a defect exists in the battery cell 123 being tested and the internal self-discharge current 208 exists, in response to connecting to the external power source 210, an external self-discharge current I_{SD} 214 may be drawn from the external power source 210 in addition to or in lieu of the internal self-discharge current I_{SD} 208 drawn from the internal power source 204. The external self-discharge current I_{SD} 214 may be measured by the current meter 212 to determine if the battery cell 123 is defective. More specifically, when the external power source 210 comes to equilibrium with the battery cell 123, the self-discharge current I_{SD} may transition from being the internal self-discharge current I_{SD} 208 to the external self-discharge current I_{SD} 214 (at least partially) which is measurable by the current meter 212.

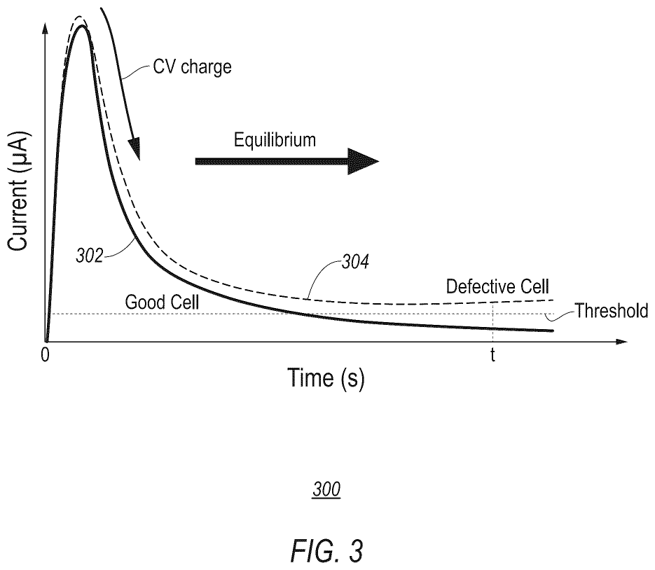

Referring to FIG. 3, a waveform diagram 300 of the external self-discharge current I_{SD} of one embodiment of the present disclosure is illustrated. With continuing reference to FIGS. 1 and 2, the waveform diagram 300 represent the micro-current equilibrium process of the external self-discharge current I_{SD} 214 after the battery cell 123 is connected to the external power source 210. The horizontal axis of the waveform diagram 300 denotes time in units of seconds and the vertical axis of the waveform diagram 300 denotes current in units of microamps. There are two waveforms illustrated in the diagram 300. More specifically, a first waveform 302 represents the external self-discharge I_{SD} 214 characteristics of a good battery cell (e.g., non-defective cell), whereas the second waveform 304 represents the external self-discharge I_{SD} 214 characteristics of a defective battery cell. As illustrated in the waveform diagram 300, the first waveform 302 and the second waveform 304 may exhibit similar patterns, which rapidly increase immediately after the battery cell 123 is connected to the external power source 210 at time 0. Following the peak of the current, the external power source 210 achieves equilibrium with the battery cell 123 and the external discharge current I_{SD} 214 starts to reduce and stabilize. A time threshold t may be utilized to define a stabilizing point after which the current 214 is measured by the current meter 212 and compared with a current threshold to determine if the self-discharge current I_{SD} 214 indicates a cell defect. For instance, the current threshold in the present example may be 5 μA. As illustrated, the current magnitude for the first waveform 302 is below the threshold after the stabilizing point t, which indicates the associated battery cell is not defective (e.g., operable), whereas the current magnitude for the second waveform 304 is above the threshold after the stabilizing point t, which indicates the associated battery cell is defective.

Referring again to FIG. 2, the system 200 may further include a system controller 216 configured to control and coordinate the defective cell detecting process. For instance, the system controller 216 may be provided with one or more processors configured to perform instructions, commands, and other routines in support of the processes described herein. The system controller 216 may be configured to execute instructions of software applications to perform operations such as data processing and analysis, machine learning, and artificial intelligence algorithms. Such software applications and other data may be maintained in a non-volatile manner using a variety of types of computer-readable storage medium onboard and/or remote from the system controller 216.

The system controller 216 may further be configured to drive or otherwise communicate with an actuator 218 configured to perform operational maneuvers to one or more battery cells 123. As an example, the actuator 118 may include one or more machinery arms (not shown) or electric motors (not shown) to facilitate placing and/or removing one or more of the battery cells 123 from the manufacturing process as monitored and directed by the system controller 216. For instance, responsive to detecting one or more of the battery cells 123 are defective based on the external self-discharge current I_{SD} 214, the system controller 216 may command the actuator 218 to remove and/or displace the defective battery cells 123 accordingly.

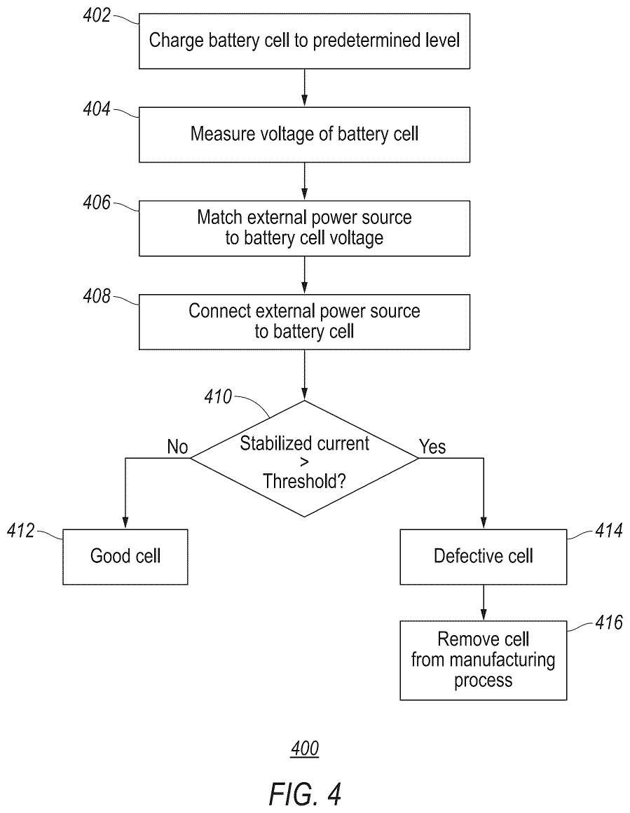

Referring to FIG. 4, an example flow diagram of a process 400 for detecting defective battery cells based on self-discharge current is illustrated. With continuing reference to FIGS. 1-3, operations of the process 400 may be primarily performed by the system controller 216 individually or in combination with other components of the system 200. At operation 402, the system 200 charges the newly formed battery cell 123 to a predefined SOC (e.g., 50%) via a charger. The charger may be provided with a predefined voltage and power rating to supply a predefined amount of electric energy into the battery cell 123.

At operation 404, once disconnected from the charger, the terminal voltage across the positive and negative terminals of the battery cell 123 is measured via a voltage meter. Each battery cells 123 being evaluated may have a slightly different voltage across the terminals due to individual differences. The voltage measurement may consider the individual differences to provide a more accurate self-discharge detection for each of the battery cells 123.

In response to determining the terminal voltage of the battery cell 123 being evaluated, at operation 406 the system controller 216 adjusts the output voltage of the external power source 210 using the measured battery cell voltage. As discussed above, the output voltage of the external power source 210 should be accurately matched to the battery cell voltage to accurately detect any self-discharge current. If the output voltage of the external power source is too low (e.g., lower than the OCV of the battery cell 123), no external self-discharge current I_{SD} 214 will flow from the external power source 210 to the battery cell 123 and thus the current meter 212 will be unable to detect the self-discharge current even if the internal self-discharge current I_{SD} 208 is present. On the other hand, if the voltage of the external power source 210 is significantly above the voltage of the battery cell 123, the external power source may operate as a charger to charge the battery cell 123 even if no internal self-discharge exists. In this case, the charging current may be detected by the current meter and misidentified as the external self-discharge current I_{SD} 214. Therefore, the voltage of the external power source 210 should closely match the voltage of the battery cell 123 as measured. In one example, it may be preferable to adjust the voltage of the external power source 210 to be slightly higher (e.g., 2 μV higher) than the battery cell voltage to facilitate the external self-discharge current I_{SD} 214 detections.

At operation 408, the external power source 210 is connected to the battery cell 123 via the current meter 212.

At operation 410, the current meter 212 measures the stabilized external self-discharge current I_{SD} 214 after the external power source 210 achieves equilibrium with the battery cell 123. The external self-discharge current I_{SD} 214 is compared with a current threshold via the system controller 216. The current threshold may be a fix threshold. Alternatively, the current threshold may be a flexible threshold adjusted based on various factors. For instance, the current threshold may be adjusted based on the voltage of the battery cell 123 previously measured via the voltage meter. A higher battery voltage may result in a higher current threshold while a lower battery voltage may result in a lower current threshold.

If the answer for operation 410 is no, indicative of the external self-discharge current I_{SD} 214 as detected being negligible, the process proceeds to operation 412 to flag the battery cell 123 being tested as a good battery cell and the cell proceeds to the next stage of manufacturing.

Otherwise, if the answer for operation 410 is yes, indicative of a significant amount of the external self-discharge current I_{SD} 214 having been detected, the process proceeds to operation 414 to flag the battery cell 123 being evaluated as a defective cell (or a potentially defective cell).

At operation 416, the defective cell is removed from the manufacturing process by the actuator 218 for further examination.

In addition to detecting defective battery cells, the present disclosure may be further utilized to identify and/or classify battery grades based on the self-discharge current detection under essentially the similar concept. Battery cells may be classified into different grades for different applications. For instance, battery cells 123 with negligible self-discharge may be classified as higher grade (e.g., Grade A) and utilized in industries with higher requirements such as the aviation industry. Battery cells with higher self-discharge may be classified as lower grades and utilized in industries with lower requirements.

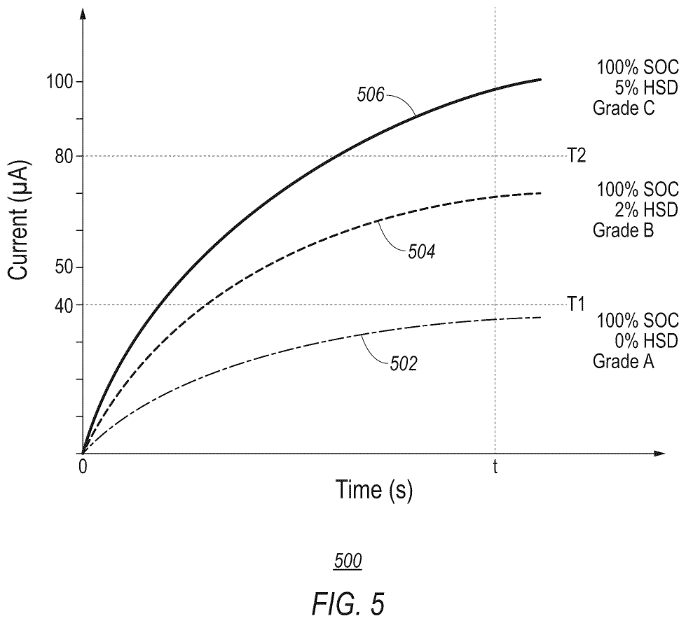

Referring to FIG. 5, a waveform diagram 500 illustrating the current characteristics of different grade battery cells of one embodiment of the present disclosure is illustrated. Similar to the waveform diagram 300, the horizontal axis of the waveform diagram 500 denotes time in units of seconds and the vertical axis denotes current in units of microamps. Different from the waveform diagram 300, the vertical axis of the waveform diagram 500 indicates a current supplied from the external power source 210 that is needed to keep the battery cell voltage unchanged over time. Due to the self-discharge, the electric energy may be continuously drawn from the external power source 210 to the battery cell 123 once connected. A greater magnitude of self-discharge may result in a higher external self-discharge current measured by the current meter 210 over time.

Referring to the waveform diagram 500, there are three waveforms illustrated. A first waveform 502 represents the current characteristics of a first battery cell with 0% higher self-discharge (HSD). A second waveform 504 represents the current characteristics of a second battery cell with 2% HSD. A third waveform 504 represents the current characteristics of a third battery cell with 5% HSD. All of the three battery cells are fully charged to 100% SOC in the present example. The HSD may be associated with a magnitude of self-discharge by cach respective battery cell 123. A lower HSD may represent a lower magnitude of self-discharge by the battery cell, which is desirable, whereas a higher HSD may represent a higher magnitude of self-discharge by the battery which is undesirable in general. The current measurement may be performed at a time threshold t (e.g., 60 seconds) to determine the current required for each battery cell being evaluated. The current may be compared with one or more current thresholds to determine the grade of each respective battery cell.

As illustrated in the waveform diagram 500, the first waveform 502 indicates a low level of current characteristics below the first current threshold T1. The battery cell 123 corresponding to the first waveform 502 may be classified as Grade A (e.g., high grade). The second waveform 504 indicates a medium level of current characteristics above the first current threshold Tl but below the second current threshold T2. The battery cell 123 corresponding to the second waveform 504 may be classified as Grade B (e.g., medium grade). The third waveform 506 indicates a low level of current characteristics above the second current threshold T2. The battery cell 123 corresponding to the third waveform 504 may be classified as Grade C (e.g., low grade).

The algorithms, methods, or processes disclosed herein can be delivered to or implemented by a computer, controller, or processing device, which can include any dedicated or programmable electronic control unit. These algorithms, methods, or processes can be stored as data and instructions executable by a computer or controller in various forms. These forms include, but are not limited to, information permanently stored on non-writable storage media, such as read-only memory devices, and information alterably stored on writable storage media, such as compact discs, random access memory devices, or other magnetic and optical media. The algorithms, methods, or processes can also be implemented as software executable objects. Alternatively, they can be embodied in whole or in part using suitable hardware components, such as application-specific integrated circuits, field-programmable gate arrays, state machines, or a combination of firmware, hardware, and software components.

While exemplary embodiments are described above, these embodiments are not intended to encompass all possible forms covered by the claims. The words used in the specification serve as descriptions rather than limitations, and it is understood that various changes can be made without departing from the spirit and scope of the disclosure. The terms “processor” and “processors” as well as “controller” and “controllers” can be used interchangeably herein.

As previously mentioned, the features of various embodiments may be combined to form further embodiments of the invention that may not be explicitly described or illustrated. While some embodiments might be described as offering advantages or being preferred over other embodiments or prior art implementations with respect to certain characteristics, those skilled in the art recognize that one or more features or characteristics may be adjusted to achieve desired overall system attributes, depending on the specific application and implementation. These attributes may include, but are not limited to, strength, durability, marketability, appearance, packaging, size, serviceability, weight, manufacturability, and ease of assembly. Therefore, embodiments described as less desirable than others or prior art implementations with respect to certain characteristics are not outside the scope of the disclosure and may be desirable for specific applications.

What is claimed is:

1. A method comprising:
adjusting an output voltage of a power source to match a voltage of a battery cell;
connecting the power source to the battery cell; and
removing the battery cell from a manufacturing line responsive to a magnitude of current flow from the power source to the battery cell being greater than a predefined threshold after a predefined period of time that begins with the connecting.

2. The method of claim 1 further comprising flagging the battery cell as operable responsive to the magnitude being less than the predefined threshold after the predefined period of time.

3. The method of claim 1, wherein the output voltage is at least equal to and no more than 3 μV greater than the voltage.

4. The method of claim 1 further comprising charging the battery cell to a predefined voltage.

5. The method of claim 4, wherein the predefined threshold is based on the predefined voltage.

6. The method of claim 1 further comprising measuring the voltage.

7. The method of claim 1 further comprising measuring the magnitude.

8. A test apparatus comprising:
a power source having an output voltage matched to a voltage of, and connected with, a battery cell;
a current meter configured to measure a magnitude of current flow from the power source to the battery cell; and
a controller programmed to flag the battery cell as operable responsive to the magnitude being less than a predefined threshold after a predefined period of time that begins with the power source being connected with the battery cell.

9. The test apparatus of claim 8, wherein the controller is further programmed to command removal of the battery cell from a manufacturing line responsive to the magnitude being greater than the predefined threshold after the predefined period of time.

10. The test apparatus of claim 8, wherein the controller is further programmed to command charging of the battery cell to a predefined voltage.

11. The test apparatus of claim 10, wherein the predefined threshold is based on the predefined voltage.

12. The test apparatus of claim 8, wherein the output voltage is at least equal to and no more than 3 μV greater than the voltage.

13. A method comprising:
adjusting an output voltage of a power source to a voltage of a battery cell such that the output voltage is at least equal to and no more than a predefined value greater than the voltage;
connecting the power source to the battery cell; and
grading the battery cell according to a magnitude of current flow from the power source to the battery cell.

14. The method of claim 13, wherein the battery cell is a lithium-ion battery cell.

15. The method of claim 13 further comprising charging the battery cell to a predefined voltage.

16. The method of claim 13 further comprising measuring the voltage of the battery cell.

17. The method of claim 13 further comprising measuring the current flow.
